(19) United States
(12) Patent Application Publication
(10) Pub. No.: US 2018/0340255 A1
(43) Pub. Date: Nov. 29, 2018

(54) Cobalt Oxide Film Deposition

(71) Applicant: Applied Materials, Inc., Santa Clara, CA (US)

(72) Inventors: Jing Zhou, San Jose, CA (US); Jacqueline S. Wrench, San Jose, CA (US); Jiang Lu, Milpitas, CA (US); Paul F. Ma, Santa Clara, CA (US); Mei Chang, Saratoga, CA (US)

(21) Appl. No.: 15/989,827

(22) Filed: May 25, 2018

Related U.S. Application Data
(60) Provisional application No. 62/511,928, filed on May 26, 2017.
(60) Provisional application No. 62/555,817, filed on Sep. 8, 2017.

(51) Int. Cl. C23C 16/40; H01L 21/02; C23C 16/455

(52) U.S. Cl. CPC C23C 16/406; C23C 16/45553; H01L 21/02205; H01L 21/02244

(57) ABSTRACT

Embodiments of the invention provide methods of depositing a CoOx film at lower processing temperatures and with a higher deposition rate. The methods disclosed herein use cobalt tricarbonyl compounds to form the CoOx film. Both atomic layer deposition and chemical vapor deposition techniques are useful in depositing the CoOx film.

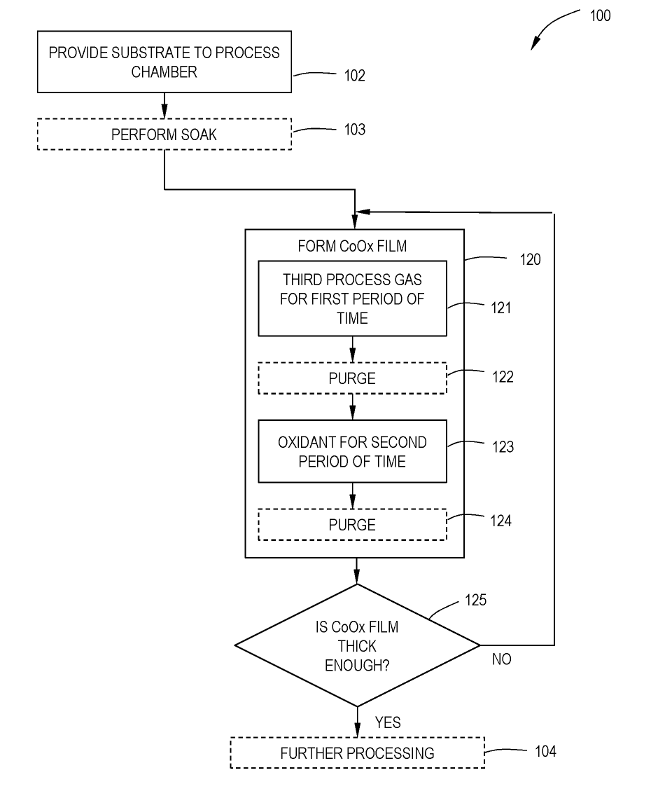

### CROSS-REFERENCE TO RELATED APPLICATIONS

This application claims priority to U.S. Provisional Application No. 62/511,928, filed May 26, 2017, and U.S. Provisional Application No. 62/555,817, filed Sep. 8, 2017, the entire disclosures of which are hereby incorporated by reference herein.

### FIELD

Embodiments of the disclosure relate to the deposition of cobalt oxide films. More particularly, embodiments of the disclosure are directed to the use of cobalt tricarbonyl nitrosyl and cobalt tricarbonyl allyl to deposit cobalt oxide films at lower temperatures and with higher deposition rates.

### BACKGROUND

Cobalt oxide films can be deposited using a chemical vapor deposition (CVD) reaction of Co precursor with ozone (method A) or oxygen remote plasma source (method B). With method A, CoOx films can be deposited at low temperature with high deposition rate. However, the hardware is complex and the daily operation is expensive. In order to enable the ozone capability in a chamber, an ozone generator is required and all chamber parts and o-rings have to be ozone compatible. In addition, a lot of facility work is involved; such as incorporation of a destruct unit for ozone gas clean-up. Moreover, an ozone generator has to be kept in continuous running mode even when the chamber is idle which adds to the daily operation cost. For method B deposition, the hardware used for an oxygen remote plasma source is relatively inexpensive, but the deposition rate is limited by oxygen radicals. It is difficult to achieve a high deposition rate even with high deposition temperatures. Additionally, cobalt precursors often have low vapor pressures and providing a full dose of cobalt precursor can take longer and may use elevated temperatures which can affect the overall thermal budget of the device being formed.

Therefore, there is a need in the art for cobalt precursors, methods and apparatus to form cobalt oxide films.

### SUMMARY

One or more embodiments of the disclosure are directed to a method of depositing a CoOx film, the method comprising exposing a substrate to a cobalt compound and an oxidizing agent to deposit a CoOx film where the cobalt compound comprises cobalt tricarbonyl allyl.

Additional embodiments of the disclosure are directed to a method of depositing a film, the method comprising exposing a substrate to a cobalt compound and an oxidizing agent to deposit a CoOx film where the cobalt compound comprises cobalt tricarbonyl nitrosyl.

Further embodiments of the disclosure are directed to a method of depositing a film, the method comprising exposing a substrate to a cobalt compound and an oxidizing agent to deposit a CoOx film where the cobalt compound comprises cobalt tricarbonyl allyl or cobalt tricarbonyl nitrosyl, without ozone and without oxygen plasma, at a temperature of less than 150 degrees Celsius.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only a typical embodiment of the disclosure and are therefore not to be considered limiting of its scope, for the disclosure may admit to other equally effective embodiments.

The FIGURE illustrates an exemplary process sequence for the formation of a CoOx film using an ALD technique to deposit the CoOx film in accordance with one or more embodiments described herein.

### DETAILED DESCRIPTION

Embodiments of the disclosure provide methods for depositing CoOx films. The process of various embodiments uses vapor deposition techniques, such as an atomic layer deposition (ALD) or chemical vapor deposition (CVD) to provide CoOx films.

Some embodiments of the disclosure advantageously provide cobalt precursors with relatively high vapor pressures. Some embodiments advantageously provide processes for cobalt oxide deposition that use relatively simple and inexpensive hardware. Some embodiments of the disclosure advantageously provide low temperature methods to deposit cobalt oxide films.

A “substrate surface”, as used herein, refers to any portion of a substrate or portion of a material surface formed on a substrate upon which film processing is performed. For example, a substrate surface on which processing can be performed include materials such as silicon, silicon oxide, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. Substrates may have various dimensions, such as 200 mm or 300 mm diameter wafers, as well as, rectangular or square panes. In some embodiments, the substrate comprises a rigid discrete material.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed sequentially to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas sequentially.

One or more embodiments of the disclosure are directed to a method of depositing a CoOx film using CVD or ALD processes

Similarly, in some embodiments, the substrate is exposed to the first reactive gas comprising the cobalt tricarbonyl compound and the second reactive gas comprising the oxidizing agent sequentially. In some embodiments, the substrate is exposed to the first reactive gas and the second reactive gas simultaneously.

In some embodiments, the deposition of the CoOx film is performed through an ALD process. In some embodiments, the deposition of the CoOx film is performed through a CVD process.

In some embodiments, plasma treatments of a reactant or as a post-treatment after the CoOx film is deposited may also be used.

The FIGURE depicts a method for forming a CoOx film on a substrate in accordance with one or more embodiments of the disclosure. The method 100 generally begins at 102, where a substrate, having a surface upon which a CoOx layer is to be formed is provided and/or positioned within a processing chamber. As used herein, a “substrate surface” refers to any substrate surface upon which a film may be formed. The substrate surface may have one or more features formed therein, one or more layers formed thereon, and combinations thereof. The substrate (or substrate surface) may be pretreated prior to the deposition process, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the CoOx film may be at least partially formed thereon. For example without limitation, in some embodiments, a nitride, an oxide, or the like, or combinations thereof may be disposed on the substrate and may have the CoOx film formed upon such layer or layers.

In some embodiments, the substrate may be exposed to an optional soak process 103 prior to beginning the deposition process to form a CoOx film on the substrate (as discussed below at 110), as shown in phantom at 103. In one or more embodiments, the method of depositing the CoOx film on the substrate does not include a soaking process.

Sub-process 120 forms a CoOx film on the substrate. The CoOx film may be formed via a cyclical deposition process, such as atomic layer deposition (ALD), or the like. In some embodiments, the forming of a CoOx film via a cyclical deposition process may generally comprise exposing the substrate to two or more process gases sequentially. In time-domain ALD embodiments, exposure to each of the process gases are separated by a time delay/pause to allow the components of the process gases to adhere and/or react on the substrate surface. Alternatively, or in combination, in some embodiments, a purge may be performed before and/or after the exposure of the substrate to the process gases, wherein an inert gas is used to perform the purge. For example, a first process gas may be provided to the process chamber followed by a purge with an inert gas. Next, a second process gas may be provided to the process chamber followed by a purge with an inert gas. In some embodiments, the inert gas may be continuously provided to the process chamber and the first process gas may be dosed or pulsed into the process chamber followed by a dose or pulse of the second process gas into the process chamber. In such embodiments, a delay or pause may occur between the dose of the first process gas and the second process gas, allowing the continuous flow of inert gas to purge the process chamber between doses of the process gases.

In spatial ALD embodiments, exposure to each of the process gases occurs simultaneously to different parts of the substrate so that one part of the substrate may be exposed to a first reactive gas while a different part of the substrate is exposed to a second reactive gas (if only two reactive gases are used). In some spatial ALD embodiments, the reactive gases are flowed into separate regions of the same processing chamber where the regions are separated by a gas curtain (which can be a combination of purge gas streams and vacuum streams). The substrate can be moved relative to the gas delivery system so that each point on the substrate is sequentially exposed to both the first and the second reactive gases. In any embodiment of a time-domain ALD or spatial ALD process, the sequence may be repeated until a predetermined layer thickness of the CoOx film is formed.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

The sub-process 120 may begin by exposing the substrate to a third reactive gas. In some embodiments, the third reactive gas comprises a cobalt tricarbonyl compound and is exposed to the substrate for a first period of time, as shown at stage 121. The compound can be adsorbed onto the substrate and will be available for further reaction with an oxidizing agent to yield a CoOx film.

In some embodiments, the third reactive gas comprises a cobalt tricarbonyl compound. In some embodiments, the third reactive gas comprises cobalt tricarbonyl allyl. In some embodiments, the cobalt tricarbonyl compound comprises cobalt tricarbonyl nitrosyl. In some embodiments, the third reactive gas consists essentially of cobalt tricarbonyl allyl. In some embodiments, the third reactive gas consists essentially of cobalt tricarbonyl nitrosyl. In some embodiments, the third reactive gas consists essentially of a mixture of cobalt tricarbonyl allyl and cobalt tricarbonyl nitrosyl. As used in this manner, the term “consists essentially of” means the cobalt precursor in the third reactive gas is greater than or equal to about 95%, 98% or 99% of the stated species, on a molar basis. The presence of a carrier, inert or diluent gas is not included in the calculation of the precursor composition.

The third reactive gas may be provided in one or more pulses or continuously. The flow rate of the third reactive gas can be any suitable flow rate including, but not limited to, flow rates in the range of about 1 to about 5000 sccm, or in the range of about 10 to about 4000 sccm, or in the range of about 25 to about 2500 sccm or in the range of about 50 to about 1000 sccm. The third reactive gas can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

The period of time that the substrate is exposed to the third reactive gas may be any suitable amount of time necessary to allow the cobalt tricarbonyl compound to form an adequate nucleation layer atop the substrate surface. For example, the process gas may be flowed into the process chamber for a period of about 0.1 seconds to about 90 seconds. In some time-domain ALD processes, the third reactive gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert gas may additionally be provided to the process chamber at the same time as the third reactive gas. The inert gas may be mixed with the third reactive gas (e.g., as a diluent gas or carrier gas) or separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, combinations thereof, or the like. In one or more embodiments, the third reactive gas is mixed with argon prior to flowing into the process chamber.

The temperature of the substrate during deposition can be controlled, for example, by setting the temperature of the substrate support or susceptor. In some embodiments the substrate is held at a temperature in the range of about 50° C. to about 250° C., or in the range of about 75° C. to about 200° C., or in the range of about 80° C. to about 150° C., or in the range of about 100° C. to about 150° C. In one or more embodiments, the substrate is maintained at a temperature less than about 150° C., or less than about 125° C., or less than about 100° C., or less than about 80° C.

Next, at stage 122, the process chamber (especially in time-domain ALD) may be purged using an inert gas. (This may not be needed in spatial ALD processes as there is a gas curtain separating the reactive gases.) The inert gas may be any inert gas, for example, such as argon, helium, neon, or the like. In some embodiments, the inert gas may be the same, or alternatively, may be different from the inert gas provided to the process chamber during the exposure of the substrate to the third reactive gas at 121. In embodiments where the inert gas is the same, the purge may be performed by diverting the third reactive gas from the process chamber, allowing the inert gas to flow through the process chamber, purging the process chamber of any excess third reactive gas components or reaction byproducts. In some embodiments, the inert gas may be provided at the same flow rate used in conjunction with the third reactive gas, described above, or in some embodiments, the flow rate may be increased or decreased. For example, in some embodiments, the inert gas may be provided to the process chamber at a flow rate of greater than 0 to about 10000 sccm to purge the process chamber. In spatial ALD, purge gas curtains are maintained between the flows of reactive gases and purging the process chamber may not be necessary. In some embodiments of a spatial ALD process, the process chamber or region of the process chamber may be purged with an inert gas.

The flow of inert gas may facilitate removing any excess third reactive gas components and/or excess reaction byproducts from the process chamber to prevent unwanted gas phase reactions of the third and fourth process gases. For example, the flow of inert gas may remove excess third reactive gas from the process chamber, preventing a reaction between the cobalt tricarbonyl compound and an oxidizing agent.

Next, at 123, the substrate is exposed to a fourth process gas for a second period of time. The fourth process gas reacts with the cobalt tricarbonyl compound on the substrate surface to create a CoOx film. In some embodiments, fourth reactive gas comprises an oxidizing agent. In some embodiments, the fourth reactive gas comprises oxygen. In some embodiments, the oxidizing agent comprises water. In some embodiments, the oxidizing agent comprises ozone. In some embodiments, the oxidizing agent comprises oxygen plasma (either direct or remote). In some embodiments, the fourth reactive gas comprises one or more of O₂, O₃, H₂O, or plasmas thereof. In one or more embodiments, the fourth reactive gas is selected to deposit a metal oxide film.

In some embodiments, the fourth reactive gas comprises oxygen. The oxygen gas may be supplied to the substrate surface at a flow rate greater than the cobalt tricarbonyl gas concentration. In one or more embodiments, the flow rate of O₂ is greater than about 1 time that of the cobalt tricarbonyl gas, or about 100 times that of the cobalt tricarbonyl gas, or in the range of about 3000 to 5000 times that of the cobalt tricarbonyl gas. The oxygen gas can be supplied, in time-domain ALD, for a time in the range of about 1 sec to about 30 sec, or in the range of about 5 sec to about 20 sec, or in the range of about 10 sec to about 15 sec. The oxygen gas can be supplied at a pressure in the range of about 1 Torr to about 30 Torr, or in the range of about 5 Torr to about 25 Torr, or in the range of about 10 Torr to about 20 Torr, or up to about 50 Torr. The substrate temperature can be maintained at any suitable temperature. In one or more embodiments, the substrate is maintained at a temperature less than about 150° C., or at a temperature about the same as that of the substrate during the cobalt tricarbonyl compound deposition.

In some embodiments, the fourth reactive gas comprises oxygen radicals. The oxygen radicals can be generated by any suitable means. For example, oxygen radicals, which may be more reactive than ground state oxygen atoms, can be generated in a remote plasma source or by passing the oxidizing agent across a hot wire.

Next, at 124, the process chamber may be purged using an inert gas. The inert gas may be any inert gas, for example, such as argon, helium, neon, or the like. In some embodiments, the inert gas may be the same, or alternatively, may be different from the inert gas provided to the process chamber during previous process steps. In embodiments where the inert gas is the same, the purge may be performed by diverting the fourth reactive gas from the process chamber, allowing the inert gas to flow through the process chamber, purging the process chamber of any excess fourth reactive gas components or reaction byproducts. In some embodiments, the inert gas may be provided at the same flow rate used in conjunction with the fourth reactive gas, described above, or in some embodiments, the flow rate may be increased or decreased. For example, in some embodiments, the inert gas may be provided to the process chamber at a flow rate of greater than 0 to about 10,000 sccm to purge the process chamber.

While the generic embodiment of the processing method shown in the FIGURE includes only two pulses of reactive gases, it will be understood that this is merely exemplary and that additional pulses of reactive gases may be used. The pulses can be repeated in their entirety or in part. For example, in an embodiment which utilizes three reactive gasses, all three pulses could be repeated or only two can be repeated. This can be varied for each cycle.

Next, at 125, it is determined whether the CoOx has achieved a predetermined thickness. If the predetermined thickness has not been achieved, the method returns to 121 to continue forming the CoOx film until the predetermined thickness is reached. Once the predetermined thickness has been reached, the method can either end or proceed to 104 for optional further processing (e.g., bulk deposition of a metal or other metal film). In some embodiments, the bulk deposition process may be a CVD process. Upon completion of deposition of the CoOx to a desired thickness, the method 100 generally ends and the substrate can proceed for any further processing. For example, in some embodiments, a CVD process may be performed to bulk deposit the CoOx to a target thickness. For example in some embodiments, the CoOx film may be deposited via ALD or CVD reaction of the cobalt tricarbonyl compound and oxygen radicals to form a total layer thickness of about 10 to about 10,000 Å, or in some embodiments, about 10 to about 1000 Å, or in some embodiments, about 500 to about 5,000 Å.

After deposition of the CoOx film, the substrate can be subjected to a post-process 104. The post-process 104 can be any suitable process including, but not limited to, treatment, etching and annealing. The post-process 104 can occur in the same processing chamber or different processing chamber than sub-process 120.

While not illustrated within the FIGURE, in some embodiments, the CoOx film is deposited by a thermal CVD processor a plasma enhanced CVD process.

During such a CVD process, the substrate is positioned on a pedestal which is configured to heat the substrate to a suitable processing temperature. In some embodiments, the substrate is heated to a temperature in the range of about room temperature to about 200° C. In one or more embodiments, the substrate is heated to a temperature in the range of about 50° C. to about 200° C., or in the range of about 75° C. to about 175° C., or in the range of about 100° C. to about 150° C. In some embodiments, the substrate is maintained at a temperature less than or equal to about 175° C., 150° C. or 125° C. during formation of the CoOx film.

Next, a cobalt precursor is flowed into the processing chamber. The cobalt precursor can be a solid or liquid contained in an ampoule. A carrier gas can be flowed through the ampoule containing the cobalt precursor to carry vaporized precursor molecules from the ampoule headspace to the processing chamber. The ampoule can be heated to increase the vapor pressure of the cobalt precursor so that more of the precursor can be flowed to the processing chamber in a given time period. In some embodiments, the carrier gas comprises one or more of argon, helium, nitrogen, hydrogen, or other inert gases. The carrier gas comprising the gaseous cobalt precursor is flowed into the processing chamber.

In some embodiments, the cobalt precursor comprises a cobalt tricarbonyl compound. In some embodiments, the cobalt precursor comprises cobalt tricarbonyl allyl. In some embodiments, the cobalt precursor comprises cobalt tricarbonyl nitrosyl. In some embodiments, the cobalt precursor consists essentially of cobalt tricarbonyl allyl. In some embodiments, the cobalt precursor consists essentially of cobalt tricarbonyl nitrosyl. In some embodiments, the cobalt precursor consists essentially of a mixture of cobalt tricarbonyl allyl and cobalt tricarbonyl nitrosyl. As used in this manner, the term “consists essentially of” means the cobalt precursor in the third reactive gas is greater than or equal to about 95%, 98% or 99% of the stated species, on a molar basis. The presence of a carrier, inert or diluent gas is not included in the calculation of the precursor composition.

Next, an oxidizing agent (or oxidant) is flowed into the processing chamber and allowed to mix with the cobalt precursor. The cobalt precursor and the oxidizing agent can be mixed prior to flowing into the processing chamber or can remain separate until both gases enter the processing chamber.

The cobalt precursor and oxidizing agent can be flowed into the processing chamber with the same start and stop times, or one can be pulsed into a flow of the other. For example, in some embodiments, the oxidizing agent is flowed into the processing chamber and the carrier gas comprising the cobalt precursor is pulsed into the processing chamber or into the flow of oxidizing agent. The pulse length and number of pulses can be varied.

In some embodiments, the oxidizing agent comprises oxygen. In some embodiments, the oxidizing agent comprises water. In some embodiments, the oxidizing agent comprises ozone. In some embodiments, the oxidizing agent comprises oxygen plasma (either direct or remote). In some embodiments, the oxidizing agent comprises one or more of O₂, O₃, H₂O, or plasmas thereof. In one or more embodiments, the oxidizing agent is selected to deposit a metal oxide film.

In some embodiments, the oxidizing agent comprises oxygen. The oxygen gas may be supplied to the substrate surface at a flow rate greater than the cobalt precursor. In one or more embodiments, the flow rate of O₂ is greater than about 1 time that of the cobalt precursor, or about 100 times that of the cobalt precursor, or in the range of about 3000 to 5000 times that of the cobalt precursor. The oxygen gas can be supplied for a time in the range of about 1 sec to about 30 sec, or in the range of about 5 sec to about 20 sec, or in the range of about 10 sec to about 15 sec. The oxygen gas can be supplied at a pressure in the range of about 1 Torr to about 30 Torr, or in the range of about 5 Torr to about 25 Torr, or in the range of about 10 Torr to about 20 Torr, or up to about 50 Torr. The substrate temperature can be maintained at any suitable temperature. In one or more embodiments, the substrate is maintained at a temperature less than about 150° C., or at a temperature about the same as that of the substrate during the cobalt precursor deposition.

In some embodiments, the oxidizing agent comprises oxygen radicals. The oxygen radicals can be generated by any suitable means. For example, oxygen radicals, which may be more reactive than ground state oxygen atoms, can be generated in a remote plasma source or by passing the oxidizing agent across a hot wire.

Next, the deposition chamber is purged to remove any excess carrier gas, unreacted cobalt precursor, byproducts and reaction products. Purging the deposition chamber stops the formation of the CoOx film.

At this point it can be determined whether the CoOx film has achieved a predetermined thickness. If the predetermined thickness has not been achieved, the CVD process is repeated to continue forming the CoOx film until the predetermined thickness is reached.

In some embodiments, the CoOx film is deposited at a temperature less than about 150 degrees Celsius. In some embodiments, the CoOx film is deposited at a temperature less than about 130 degrees Celsius. the CoOx film is deposited at a temperature less than about 120 degrees Celsius. the CoOx film is deposited at a temperature less than or equal to about 100 degrees Celsius. In some embodiments, the CoOx film is deposited at a temperature greater than or equal to 80 degrees Celsius.

In some embodiments, the CoOx film is deposited at a rate greater than 1 Å per second. In some embodiments, the CoOx film is deposited at a rate of between about 1 Å and about 2 Å per second.

Some embodiments of the disclosure are directed to methods of depositing CoOx films. Those skilled in the art will understand that the film deposited may have a nonstoichiometric amount of cobalt, oxygen, nitrogen, carbon and/or boron atoms on an atomic basis, depending on the composition of the film.

In some embodiments, the CoOx film comprises greater than or equal to about 95, 96, 97, 98 or 99 atomic percent cobalt oxide, meaning that the sum of cobalt and oxygen atoms in the film are greater than or equal to about 95%, 96%, 97%, 98% or 99% of the total film. In one or more embodiments, the sum of C, N, and halogen atoms is less than or equal to about 5, 4, 3, 2 or 1 atomic percent of the CoOx film.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a film, the method comprising:
exposing a substrate to a cobalt compound comprising cobalt tricarbonyl allyl; and
exposing the substrate to an oxidizing agent.

2. The method of claim 1, wherein the CoOx film is deposited at a rate of greater than about 1 Å per second.

3. The method of claim 1, wherein the CoOx film is deposited at a rate of about 2 Å per second.

4. The method of claim 1, wherein the CoOx film is deposited without ozone.

5. The method of claim 1, wherein the CoOx film is deposited without oxygen plasma.

6. The method of claim 1, wherein the CoOx film is deposited without oxygen.

7. The method of claim 1, wherein the CoOx film is deposited with oxygen.

8. The method of claim 1, wherein the CoOx film is deposited at a temperature less than or equal to about 150 degrees Celsius.

9. The method of claim 1, wherein the CoOx film is deposited at a temperature less than or equal to about 100 degrees Celsius.

10. A method of depositing a film, the method comprising:
exposing a substrate to a cobalt compound comprising cobalt tricarbonyl nitrosyl; and
exposing the substrate to an oxidizing agent.

11. The method of claim 10, wherein the CoOx film is deposited at a rate of greater than about 1 Å per second.

12. The method of claim 10, wherein the CoOx film is deposited at a rate of about 2 Å per second.

13. The method of claim 10, wherein the CoOx film is deposited without ozone.

14. The method of claim 10, wherein the CoOx film is deposited without oxygen plasma.

15. The method of claim 10, wherein the CoOx film is deposited without oxygen.

16. The method of claim 10, wherein the CoOx film is deposited with oxygen.

17. The method of claim 10, wherein the CoOx film is deposited at a temperature less than or equal to about 150 degrees Celsius.

18. The method of claim 10, wherein the CoOx film is deposited at a temperature less than or equal to about 100 degrees Celsius.

19. A method of depositing a film, the method comprising:
exposing a substrate to a cobalt compound; and
exposing the substrate to an oxidizing agent;
wherein, the cobalt compound comprises cobalt tricarbonyl allyl or cobalt tricarbonyl nitrosyl, and the CoOx film is deposited at a rate of greater than about 1 Å per second, without ozone and without oxygen plasma, at a temperature of less than 150 degrees Celsius.

20. The method of claim 19, wherein the CoOx film is deposited at a temperature less than or equal to about 100 degrees Celsius.
